(19) United States
(12) Patent Application Publication
(10) Pub. No.: US 2016/0238795 A1
(43) Pub. Date: Aug. 18, 2016

(54) LOSS COMPENSATED OPTICAL SWITCHING

(71) Applicant: HEWLETT PACKARD ENTERPRISE DEVELOPMENT LP, Houston, TX (US)

(72) Inventors: Michael Renne Ty Tan, Palo Alto, CA (US); Sagi Varghese Mathai, Palo Alto, CA (US); Wayne Victor Sorin, Palo Alto, CA (US); Paul Kessler Rosenberg, Palo Alto, CA (US)

(73) Assignee: Hewlett-Packard Development Company, L.P., Houston, TX (US)

(21) Appl. No.: 15/027,085

(22) PCT Filed: Oct. 9, 2013
(86) PCT No.: PCT/US2013/064137

§ 371 Date: Apr. 4, 2016

(51) Int. Cl. G02B 6/35; G02B 6/293; H01S 5/50; G02F 1/313

(52) U.S. Cl. CPC G02B 6/3596; G02F 1/3138; G02F 1/3136; G02B 6/3546; G02B 6/29344; G02B 6/29329; H01S 5/50

(57) ABSTRACT

Loss compensated optical switching includes an optical crossbar switch and a wafer bonded semiconductor amplifier (SOA). The optical crossbar switch has a plurality of input ports and a plurality of output ports and is on a substrate of a first semiconductor material. The wafer bonded SOA includes a layer of second semiconductor material that is wafer bonded to a surface of the substrate such that a portion of the wafer bonded SOA semiconductor material layer overlies a portion of a port of the plurality of input ports. The second semiconductor material of the wafer bonded SOA is different from the first semiconductor material of the substrate.

### CROSS-REFERENCE TO RELATED APPLICATIONS

N/A

### STATEMENT REGARDING FEDERALLY SPONSORED RESEARCH OR DEVELOPMENT

N/A

### BACKGROUND

In data communications, switching is often employed to provide interconnection between data nodes via a plurality of dynamic and sometimes reconfigurable, virtual connections or channels hosted by one or more physical channels. In particular, a number of connections or channels required to fully interconnect the data nodes in a given data communication network often exceeds the available physical channels. Switching may be used to one or both of time and space multiplex the available physical channels enabling interconnection of data nodes via virtual channels within the physical channels, where the number of virtual channels is often far greater than the number of available physical channels. As result, much higher interconnection density may be provided with switching within a data communication network than would otherwise be possible without switching.

In addition to interconnection density represented by a total number of interconnected or at least interconnectable data nodes, data capacity or a speed at which data can be transferred between data nodes over a channel is typically another important consideration in data networks. While switching may help to increase data capacity by providing a better average usage of available physical channels, a demand for increased data capacity has also hastened the adoption of optical communications channels (e.g., fiber optics) in modern data communication networks. Thus, a combination of a need for greater and greater data capacity concomitant with higher and higher interconnection densities has resulted in a need for optical switching and the use of optical fabrics within data networks.

In general, optical switching within data networks may be implemented either using an optical-electrical-optical conversion switch architecture (O/E/O switching) or with a so-called ‘all optical’ switch architecture. In O/E/O switching, optical signals to be switched are first converted to an electrical signal and then switched as electronic signals using conventional electronic switching. Once switched, the electronic signals are converted back to and retransmitted as an optical signal. In all optical switching, optical signals are switched as optical signals using photonic devices without a conversion to and from an electronic signal. While O/E/O switching has certain advantages in terms of fabrication and implementation in conventional integrated circuit technology, using O/E/O switching is becoming less and less desirable due to complexity and bandwidth limitations in comparison to all optical switching. For example, an all optical switch using high speed photonic devices and operating directly on optical signals eliminates a need for the electronic signal conversion process which may reduce complexity and further tends to preserve the bandwidth inherent in optical interconnects such as fiber optical cables. However, while highly desirable in many applications, all optical switching often requires a difficult trade-off to be made between costs and performance.

### BRIEF DESCRIPTION OF THE DRAWINGS

Various features of examples in accordance with the principles described herein may be more readily understood with reference to the following detailed description taken in conjunction with the accompanying drawings, where like reference numerals designate like structural elements, and in which:

FIG. 1A illustrates a cross sectional view of a ridge-loaded optical waveguide, according to an example consistent with the principles described herein.

FIG. 1B illustrates a cross sectional view of a reverse ridge-loaded optical waveguide, according to an example consistent with the principles described herein.

FIG. 1C illustrates a cross sectional view of a strip optical waveguide, according to an example consistent with the principles described herein.

FIG. 2 illustrates a block diagram of a loss compensated optical switch, according to an example of the principles describe herein.

FIG. 3A illustrates a schematic view of an optical switch, according to an example consistent with the principles described herein.

FIG. 3B illustrates a top view of an optical switch, according to another example consistent with the principles described herein.

FIG. 3C illustrates a top view of an optical switch, according to yet another example consistent with the principles described herein.

FIG. 4 illustrates a schematic view of an optical crossbar switch, according to an example consistent with the principles described herein.

FIG. 5 illustrates a cross sectional view of a wafer bonded semiconductor amplifier (SOA), according to an example consistent with the principles described herein.

FIG. 6 illustrates a block diagram of a loss compensated optical switch system, according to an example consistent with the principles described herein.

FIG. 7 illustrates a flow chart of a method of loss compensated optical switching, according to an example consistent with the principles described herein.

Certain examples have other features that are one of in addition to and in lieu of the features illustrated in the above-referenced figures. These and other features are detailed below with reference to the above-referenced figures.

### DETAILED DESCRIPTION

Examples in accordance with the principles described herein provide loss compensated optical switching. In particular, loss compensated optical switching from a plurality of inputs to a plurality of outputs may be provided. According to the principles described herein, loss compensated optical switching employs an optical crossbar switch to provide optical signal switching and an optical amplifier to mitigate or compensate for loss in the optical crossbar switch. Further, the optical amplifier is a wafer bonded semiconductor optical amplifier, according to various examples consistent with the principles described herein. Using a wafer bonded semiconductor optical amplifier enables materials and implementation of the optical crossbar switch and the wafer bonded semiconductor optical amplifier to be chosen in a substantially independent manner. As such, performance and costs associated with the optical crossbar switch implementation are not constrained or otherwise adversely impacted by choices regarding the implementation of the wafer bonded semiconductor optical amplifier. Optical switching using loss compensated optical switching according to the principles described herein may provide high input/output port count switches with little or no optical loss, according to various examples described herein.

In some examples, a loss compensated optical switch used for loss compensated optical switching may be fabricated directly in a surface layer (e.g., thin film layer) of a semiconductor substrate. Further, a portion of the loss compensated optical switch also may be fabricated as a layer affixed to a top surface of the surface layer, according to various examples. For example, a portion of the loss compensated optical switch that includes an optical crossbar switch may employ various optical waveguides, which serve as input and output ports. The optical waveguides may be fabricated in a thin film semiconductor layer of a semiconductor-on-insulator (SOI) substrate (e.g., a silicon or polysilicon thin film layer of a silicon-on-insulator substrate). In addition, a portion of the loss compensated optical switch which includes a semiconductor optical amplifier may be fabricated using another semiconductor layer that is wafer bonded or otherwise affixed to the top surface of the SOI substrate. Through the use of wafer bonding, the semiconductor layer affixed to the semiconductor substrate surface may include a semiconductor material that differs from, and even has a lattice that is substantially dissimilar to, the semiconductor material of the surface layer of the semiconductor substrate. For example, the semiconductor material of the surface layer may be silicon while the wafer-bonded semiconductor layer may be a III-V compound semiconductor or a II-VI compound semiconductor.

Herein, the terms ‘optical amplifier’ and ‘optical switch’ by definition generally refer to one or both of a device and a structure that operates directly on an optical signal (e.g., as an amplifier or switch, respectively) without prior conversion of the optical signal into an electrical signal. For example, the optical amplifier may be a saturable active semiconductor device that directly amplifies an optical signal through stimulated emission within the semiconductor device (e.g., a laser without mirrors). Such devices are generally referred to as semiconductor optical amplifiers (SOAs).

As used herein, ‘optical waveguide’ by definition refers to a waveguide in which a propagating optical signal is confined to and propagates within a slab, sheet or strip of material. As such, a slab optical waveguide or simply a ‘slab waveguide’ is a slab of material or ‘slab layer’ that supports a propagating optical signal within the slab layer, by definition herein. According to various examples, the loss compensated optical switch employs an optical waveguide and in some examples a slab optical waveguide. In particular, the optical waveguide may include, but is not limited to, a ridge-loaded optical waveguide, an inverted or reverse ridge-loaded optical waveguide, and a strip optical waveguide. Both the ridge-loaded optical waveguide and the reverse ridge-loaded optical waveguide are slab waveguides while the strip waveguide is not considered a slab waveguide.

In some examples, a transverse dimension (width) of the optical waveguide is selected to preferentially sustain a low-order propagating mode of the optical signal. In some examples, only a single propagating mode is sustained by the optical waveguide. For example, the width may be less than a particular width such that only a first transverse electric mode (i.e., TE₁₀) can propagate. The particular width depends on a refractive index of a material of the optical waveguide, the thickness of the optical waveguide layers as well as specific physical characteristics of the optical waveguide (i.e., optical waveguide type).

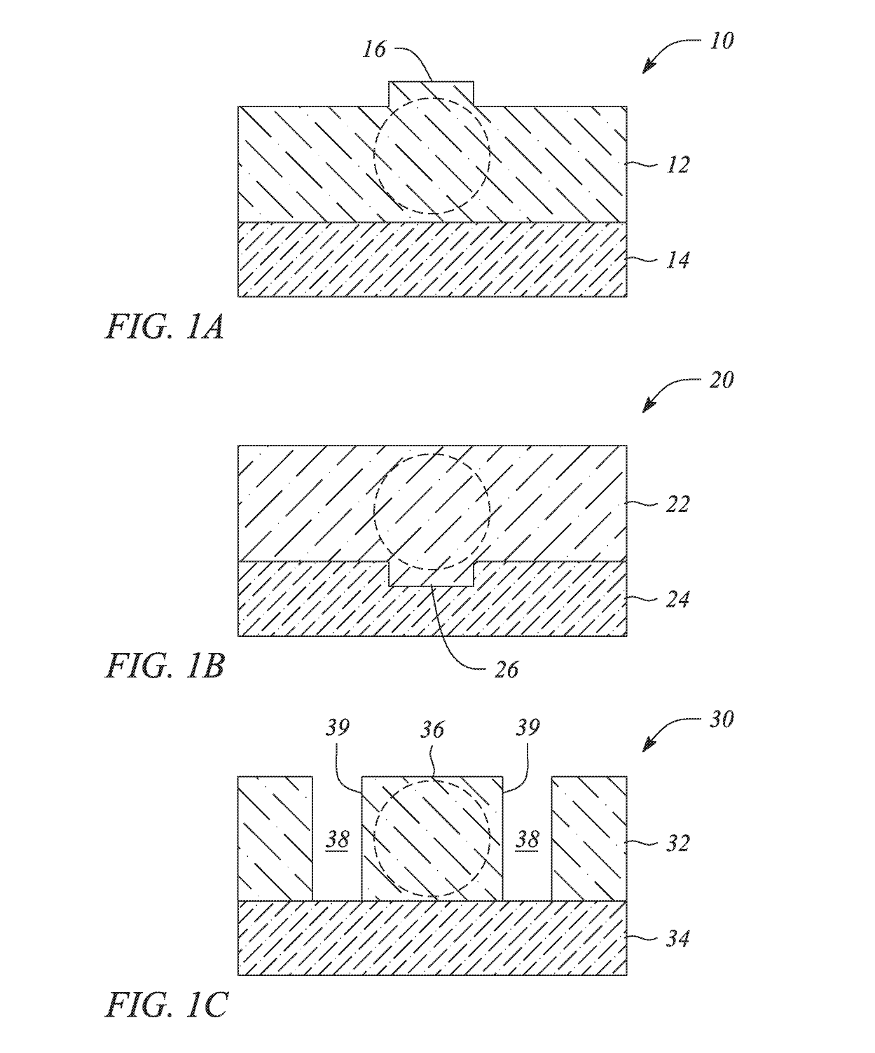

FIG. 1A illustrates a cross sectional view of a ridge-loaded optical waveguide 10, according to an example consistent with the principles described herein. The ridge-loaded optical waveguide 10 is also sometimes referred to as a ‘ridge-loaded waveguide’ or simply a ‘ridge waveguide’. The ridge-loaded optical waveguide 10 includes a slab layer 12. The slab layer 12 is or includes a material through which an optical signal propagates and is guided within the ridge-loaded waveguide 10. In particular, the material of the slab layer 12 is substantially transparent to the optical signal and further substantially all of the energy of the optical signal is confined to the slab layer 12 of the ridge-loaded optical waveguide 10, according to various examples. In some examples, the slab layer 12 may include a material such as a semiconductor material, which behaves substantially as a dielectric material with respect to its use in an optical waveguide. In other examples, the slab layer may include more than one semiconductor materials of differing bandgaps and refractive indices.

For example, the slab layer 12 may include a semiconductor material that is compatible with the optical signal such as, but not limited to, silicon (Si), gallium arsenide (GaAs), and lithium niobate (LiNbO₃). Any of a single crystalline, polycrystalline or amorphous layer of the semiconductor material may be employed, according to various examples. The transparency of the slab layer material generally affects an optical loss of the ridge-loaded waveguide. For example, the less transparent the material, the more loss is experienced by the optical signal.

In some examples (e.g., as illustrated), the slab layer 12 is supported by a support layer 14. The support layer 14 physically supports the slab layer 12. In some examples, the support layer 14 also facilitates optical confinement in the slab layer 12. In particular, the support layer 14 may include a material that differs from the material of the slab layer 12. In some examples, the support layer 14 may include a material having a refractive index that is less than a refractive index of the slab layer 12. For example, the support layer 14 may be an oxide-based insulator layer (e.g., a silicon oxide of a silicon SOI substrate) and the slab layer 12 may be silicon. In some examples, the different refractive index of the support layer 14 relative to the slab layer 12 serves to substantially confine the optical signal to the slab layer 12 (e.g., by total internal reflection).

The ridge-loaded waveguide 10 further includes a ridge 16. The ridge 16 is located on and extends above a top surface of the slab layer 12. The ridge 16 serves to ‘guide’ the optical signal within the slab layer 12 directly below the ridge 16. The presence of less material in regions surrounding the ridge 16 (i.e., that defines the ridge 16) reduces an effective index of refraction or ‘effective index’ experienced by light in surrounding region relative to the effective index at and in a vicinity of the ridge 16. The reduced effective index causes an optical signal propagating in the slab layer 12 to be ‘guided’ in the higher effective index due to the presence of the ridge 16. In particular, substantially all of the optical energy of the optical signal tends to be concentrated below but substantially adjacent to the ridge 16 within the slab layer 12. For example, as illustrated in FIG. 1A by a dashed circle, the optical signal guided by the ridge-loaded waveguide 10 may be substantially concentrated in a roughly circular region below the ridge 16. According to various examples, the ridge 16 may be formed by one or more of an etching process, a selective deposition process, a printing process, a combination thereof, or another process. The particular width and height of the ridge 16 are generally a function of a refractive index of the ridge and the underlying slab layer 12 material.

FIG. 1B illustrates a cross sectional view of a reverse ridge-loaded optical waveguide 20, according to an example consistent with the principles described herein. The reverse ridge-loaded optical waveguide 20 is also sometimes referred to simply as a ‘reverse ridge-loaded waveguide’ or a ‘reverse ridge waveguide.’ As illustrated, the reverse ridge-loaded optical waveguide 20 includes a slab layer 22 and a support layer 24. The support layer 24 includes a material having a refractive index that is less than the refractive index of the slab layer 22. The slab layer 22 may be substantially similar to the slab layer 12 of the ridge-loaded waveguide 10, described above, for example. Further, the support layer 24 may be substantially similar to the support layer 14 of the ridge-loaded waveguide 10, described above.

The reverse ridge-loaded waveguide 20 further includes a ridge 26. The ridge 26 extends from an interface between the support layer 24 and the slab layer 22 into the support layer 24. As such, the ridge 26 of the reverse ridge-loaded waveguide 20 may be referred to as a ‘buried’ ridge 26. The buried ridge 26 creates a higher effective index in a vicinity of and above the buried ridge 26 relative to a surrounding region of the slab layer 22. The higher effective index tends to confine light (e.g., the optical signal) adjacent to the buried ridge 26. Hence, as with the ridge 16 of the ridge-loaded waveguide 10 described above, the buried ridge 26 of the reverse ridge-loaded waveguide 20 serves to guide the optical signal within the slab layer 22. An example dashed circle above but substantially adjacent to the ridge 26 illustrates an approximate extent of the optical signal energy associated with an optical signal propagating in and guided by the reverse ridge-loaded waveguide 20.

FIG. 1C illustrates a cross sectional view of a strip optical waveguide 30, according to an example consistent with the principles described herein. The strip optical waveguide 30, or simply ‘strip waveguide’, includes a strip layer 32 and a support layer 34. According to various examples, a refractive index of the support layer 34 is lower than the refractive index of the strip layer 32. The strip optical waveguide 30 further includes a strip 36 formed in or from the strip layer 32. In particular, the strip 36 may be formed in the strip layer 32 by etching channels 38 to define the strip 36. The channels 38 optically isolate the strip 36 from the rest of the strip layer 32. In other examples (not illustrated), the strip 36 is substantially all of the strip layer that remains after fabrication. For example, most of an original strip layer may be removed during fabrication (e.g., by etching) to leave only the strip 36 remaining on the support layer 34. As such, channels are not formed or employed to optically isolate the strip 36, according to some examples.

The optical energy within the strip waveguide 30 is substantially confined to or within the strip 36 by the presence of sidewalls 39 of the strip 36 as well as the presence of the lower refractive index support layer 34 below the strip 36. In particular, a material boundary exists at the sidewalls 39 between a material of the strip layer 32 and air or another dielectric material adjacent thereto, e.g., within the channels 38. Similarly, another material boundary exists between the material of the strip 36 and the lower refractive index support layer 34. These material boundaries surrounding the strip 36 represent a change (i.e., a step decrease) in a refractive index experienced by an optical signal propagating in the strip 36. As a result, the optical signal is tightly bound within the strip 36 (e.g., due to total internal reflection therewithin) due to these material boundaries, according to various examples. A dashed circle within the strip 36 illustrates an approximate extent of the optical energy associated with the optical signal propagating in the strip waveguide 30, for example.

Herein, a ‘multimode interference (MMI) coupler’ is defined as an optical coupler based on self-imaging effects of an optical signal within a slab optical waveguide (e.g., a rectangular section of optical waveguide). The self-imaging effects may be used to implement MMI couplers that exhibit various coupling/splitting characteristics between an input port(s) and an output port(s) of the MMI coupler, for example. In particular, interference between various optical modes excited by an input optical signal may result in the existence of so-called ‘self images’ at different locations within the slab optical waveguide. By selecting a predetermined length and width of the slab waveguide along with a predetermined location of inputs and outputs, a wide variety of coupling/splitting configurations (e.g., including a 3-dB coupling/splitting) may be realized.

By definition herein, the term ‘semiconductor optical amplifier’ or ‘SOA’ refers to an optical amplifier based on a semiconductor gain region that includes a semiconductor material. For example, the SOA 120 may be a laser diode structure without an optical cavity (e.g., without end mirrors). Further herein, the SOA is defined as a waveguide structure that supports a transverse mode. In some examples, only a single transverse mode is supported. In operation, an optical signal is introduced or sent through an optical waveguide adjacent to the SOA. For example, the optical waveguide may have a transverse dimension on the order of or about 1-2 micron (μm) and a length of about 500-1000 μm. An optical mode in the optical waveguide overlaps or extends into an active or amplifying region of the SOA (i.e., the semiconductor gain region) to couple a portion of the optical signal into the SOA active regions (e.g., as the transverse mode). In various examples, the active region is ‘pumped’ by an electrical current that substantially fills the active region with excited electrons in a conduction band and holes in a valence band of the semiconductor material of the semiconductor gain region. If the carrier density provided by pumping is high enough, the material may have optical gain such that the SOA amplifies the coupled portion of the optical signal through stimulated emission. The coupled portion is then coupled back into the optical waveguide as an amplified optical signal.

Further, as used herein, the article ‘a’ is intended to have its ordinary meaning in the patent arts, namely ‘one or more’. For example, ‘a switch’ means one or more switches and as such, ‘the switch’ means ‘the switch(es)’ herein. Also, any reference herein to ‘top’, ‘bottom’, ‘upper’, ‘lower’, ‘up’, ‘down’, ‘front’, back’, ‘left’ or ‘right’ is not intended to be a limitation herein. Herein, the term ‘about’ when applied to a value generally means within the tolerance range of the equipment used to produce the value, or in some examples, means plus or minus 10%, or plus or minus 5%, or plus or minus 1%, unless otherwise expressly specified. Further, herein the term ‘substantially’ as used herein means a majority, or almost all, or all, or an amount with a range of about 51% to about 100%, for example. Moreover, examples herein are intended to be illustrative only and are presented for discussion purposes and not by way of limitation.

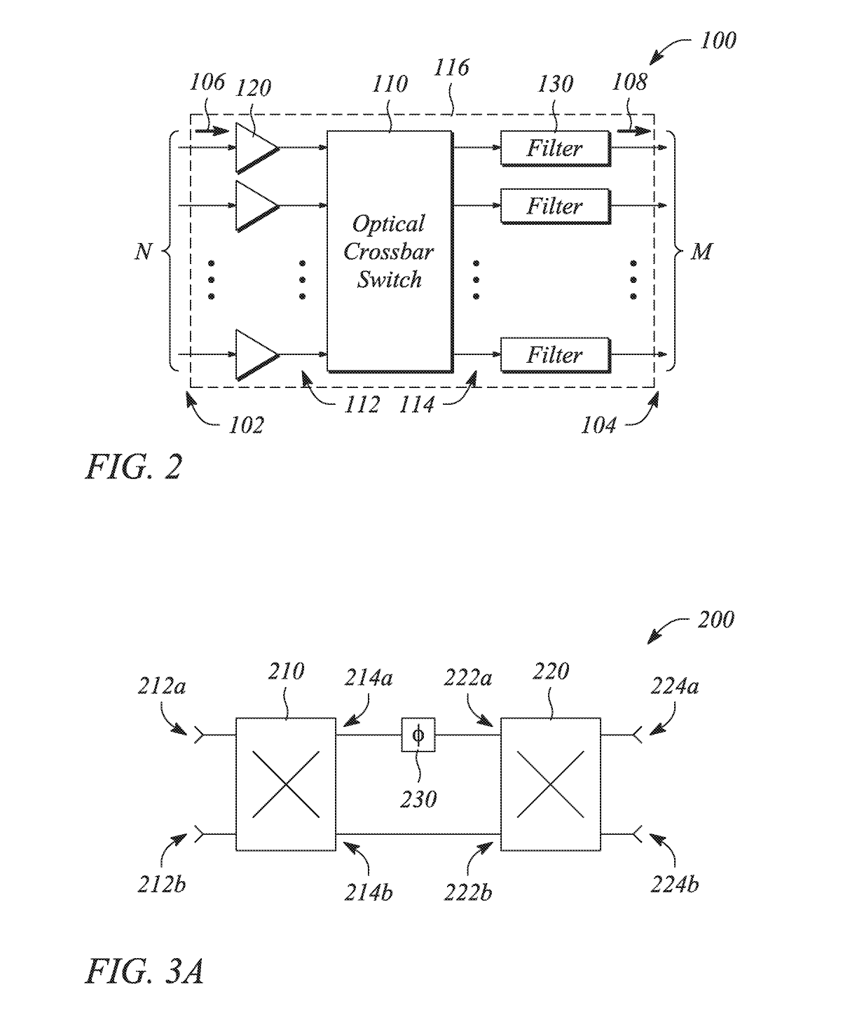

FIG. 2 illustrates a block diagram of a loss compensated optical switch 100, according to an example of the principles describe herein. According to various examples, the loss compensated optical switch 100 may include a plurality of optical inputs 102 and a plurality of optical outputs 104. The optical inputs 102 and the optical outputs 104 may include optical waveguides, for example. In some examples, the optical inputs 102 and the optical outputs 104 may interface with optical fibers or similar optical waveguides. According to various examples, the loss compensated optical switch 100 is configured to receive an optical signal 106 at an optical input 102 (e.g., from the interfaced optical fibers). The loss compensated optical switch 100 is further configured to selectively route or distribute the optical signal 106 to one or more of the optical outputs 104 as an output optical signal 108.

For example, the loss compensated optical switch 100 may be configured to selectively route the optical signal 106 from a first optical input 102 to a first optical output 104. In another example, the loss compensated optical switch 100 may be reconfigured to route the optical signal 106 from the first optical input 102 to another optical output 104 (e.g., a second, third, fourth, fifth, etc., optical output 104). Similarly, another optical signal 106 at another optical input 102 (e.g., a second, third, fourth, etc.) may be selectively routed to the first, second, third, fourth, etc., optical outputs 104. In some examples, the loss compensated optical switch 100 may represent a non-blocking switch matrix. Furthermore, according to some examples, the optical signal 106 at an optical input 102 of the loss compensated optical switch 100 may be routed to a plurality of optical outputs 104 (e.g., a second, third, fourth, etc. optical output 104) in a substantially simultaneous manner (i.e., in parallel). In other words, the optical signal 106 at an optical input 102 may be simultaneously broadcast to a plurality of optical output ports 104 by the loss compensated optical switch 100, according to some examples. Routing and reconfiguring may be dynamic and performed in situ, according to various examples.

According to various examples, optical loss that may be experienced by the optical signal 106 during passage through the loss compensated optical switch 100 is compensated for or mitigated by the loss compensated optical switch 100. In some examples, the loss compensated optical switch 100 may be substantially without significant optical loss (e.g., lossless) with respect to the optical signal 106 passing from an input 102 to an output 104. According to various examples, the loss compensated optical switch 100 includes integral optical amplification to provide loss compensation. Further, according to various examples, the loss compensated optical switch 100 is a fully optical switch in that the optical signal 106 remains an optical signal (i.e., is not converted to an electrical signal) from the optical input 102 to the optical output 104.

As illustrated in FIG. 2, the loss compensated optical switch 100 includes an optical crossbar switch 110 having a plurality of input ports 112 and a plurality of output ports 114. For example, the plurality of input ports 112 may include N input ports 112, where N is an integer greater than one (i.e., N>1). Similarly, the plurality of output ports 114 may include M output ports 114, where M is an integer greater than one (i.e., M>1). In some examples, the number of input ports N and the number of output ports M of the optical crossbar switch 110 are not the same (i.e., N≠M). For example, the optical crossbar switch 110 may include four (4) input ports 112 and eight (8) output ports 114 (i.e., N=4 and M=8). In other examples, the optical crossbar switch 110 may have the same number of input ports 112 as output ports 114 (i.e., N=M). For example, the optical crossbar switch 110 may have two (2) input ports 112 and two (2) output ports 114 (i.e., M=N=2).

According to various examples, the optical crossbar switch 110 is on or substantially supported by a substrate 116. The substrate 116 includes a first semiconductor material. In particular, the optical crossbar switch 110 may be fabricated in a surface of the substrate 116 employing the first semiconductor material. For example, optical waveguides of the optical crossbar switch 110 may be provided (e.g., as ridges or strips) in the substrate surface. Characteristics of the first semiconductor material may be employed to accomplish switching within the optical crossbar switch 100, for example (e.g., see discussion below).

In some examples, the first semiconductor material may be or include a group IV semiconductor such as, but not limited to, silicon (Si) or germanium (Ge). In other examples, the first semiconductor material may include, but is not limited to, a III-V compound semiconductor and a II-VI compound semiconductor. In some examples, the first semiconductor material is silicon and the substrate 116 is a silicon semiconductor-on-insulator (i.e., a silicon SOI) substrate 116. In some examples, the input and output ports 112, 114 are optical waveguides provided in a silicon surface of the silicon SOI substrate 116. The optical waveguide may be any of a variety of optical waveguides including, but not limited to, a ridge-loaded waveguide, a reverse ridge-loaded waveguide and a strip optical waveguide.

In some examples, the optical crossbar switch 110 includes a plurality of optical switches connecting between the input ports 112 and the output ports 114 to form a switch matrix. According to various examples, any of a variety of optical switches may be employed to form the switch matrix. For example, solid-state optical switches that may be used to realize the optical crossbar switch 110 include, but are not limited to, one or more of Mach-Zehnder interferometer (MZI) based switches, directional coupler based switches, total internal reflection switches, and Y-branch or digital optical switches. Optical switches based on the MZI may include, but are not limited to, MZI-based switches that employ a multimode interference (MMI) coupler. In addition or alternatively to solid-state optical switches, various other optical switches may be used including, but not limited to, one or both of micro electro-mechanical system (MEMS) based switches (e.g., micro-mirrors) and polarization shift based optical switches may also be employed.

According to various examples, the plurality optical switches may be arranged in any of a variety of switch matrix configurations including, but not limited to, various non-blocking switch configurations. Example non-blocking switch configurations include, but are not limited to, a crossbar switch configuration, a switch configuration based on the Benes architecture, a switch configuration based on the Spanke-Benes (n-Stage Planar) architecture, and a Spanke architecture based switch configuration. Herein, all switch matrix configurations will be referred to generically as a ‘crossbar’ switch for simplicity of discussion and without loss of generality unless reference to a specific or particular switch matrix configuration is necessary for proper understanding. Hence, by definition herein, the term ‘optical crossbar switch’ explicitly refers to and includes any multiport optical switch matrix that may be used to interconnect a plurality of input and output ports, unless stated otherwise.

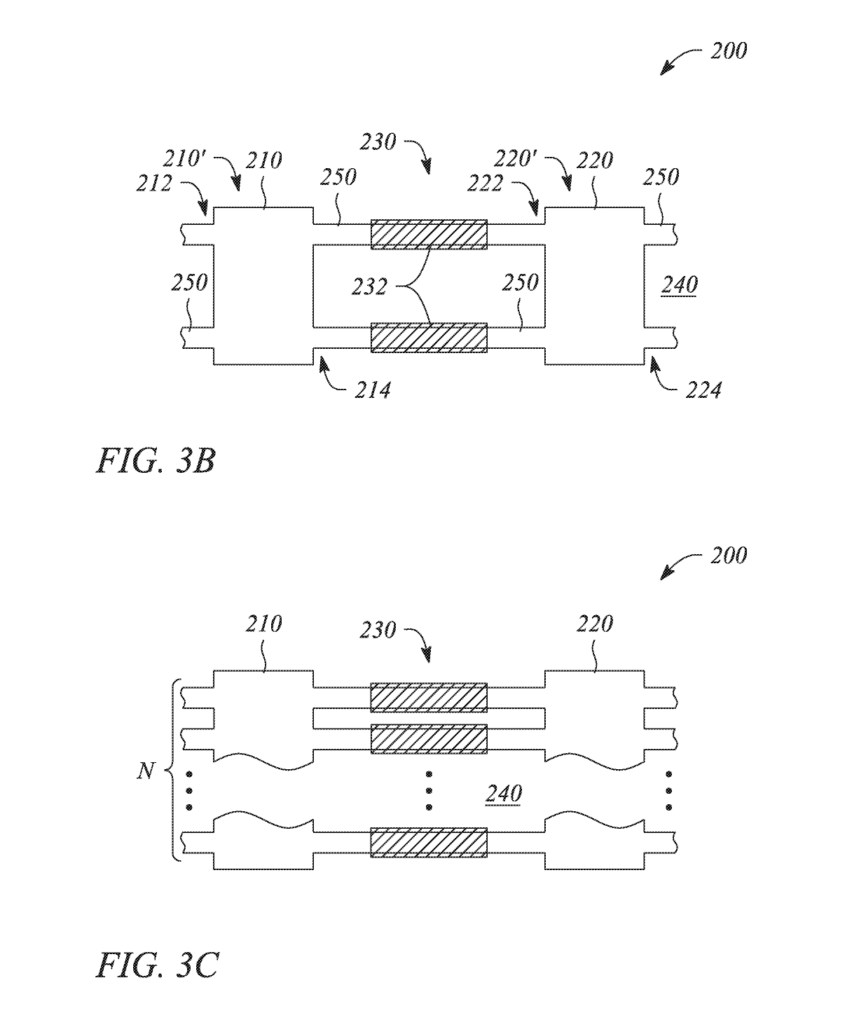

FIG. 3A illustrates a schematic view of an optical switch 200, according to an example consistent with the principles described herein. In particular, the optical switch 200 is an example of a Mach-Zehnder interferometer (MZI) optical switch 200. As illustrated, the MZI optical switch 200 includes a first coupler 210 and a second coupler 220. The first coupler 210 includes a pair of input ports 212a, 212b that are or serve as inputs (e.g., through connecting optical waveguides) of the MZI optical switch 200. The second coupler 220 includes a pair of output ports 224a, 224b that are or serve as outputs (e.g., through connecting optical waveguides) of the MZI optical switch 200.

As illustrated, an output of the first coupler 210 is connected to an input of the second coupler 220. In particular, the first coupler 210 has a pair of output ports 214a, 214b, as illustrated. Further, as illustrated, the output ports 214a, 214b of the first coupler 210 are each connected to a different input port of a pair of input ports 222a, 222b, of the second coupler 220. In some examples, one or both of the first coupler 210 and the second coupler 220 are quadrature (i.e., 90-degree) couplers. In other examples, one or both of the first and second couplers 210, 220 may be an in-phase (i.e., 0-degree) or another type (e.g., 180-degree) of coupler. Note that with respect to a quadrature coupler, optical power at an input is divided substantially equally and then distributed to the two outputs thereof (i.e. the quadrature coupler is a 3 dB coupler).

The MZI optical switch 200 further includes a phase shifter 230 in the connection between the first and second couplers 210, 220. As illustrated, the phase shifter 230 is located in one of two connections between the first and second couplers 210, 220. In other examples (not illustrated), a plurality of phase shifters may be employed on a plurality of connections (e.g., both or all connections) between the couplers 210, 220.

According to some examples, the phase shifter 230 may employ one or both of an electric field induced and a carrier induced refractive index change to provide the change in phase. The change in refractive index produces a concomitant change in an electrical length or a ‘phase length’ that results in a phase shift of the phase shifters 230. As such, according to some examples, the phase shifter 230 may include a length of optical waveguide that forms the connection between the first and second couplers 210, 220 and an electrode configured to influence and thus induce the refractive index change in the optical waveguide (i.e., in a material of the optical waveguide). For example, the electrode may serve as a source or a sink of carriers to change a density of carriers in a material of the optical waveguide. The change in carrier density, in turn, results in a change of the refractive index of the optical waveguide due to one or more of band filling, bandgap shrinkage and various plasma effects within the optical waveguide material. In another example, the electrode may provide an electric field to induce the refractive index change according to one or both of the linear or ‘Pockels’ electrooptical effect and the quadratic or ‘Kerr/Franz-Keldish’ electrooptical effect.

The MZI optical switch 200, as illustrated in FIG. 3A, is switched between switch states by changing a phase state in the connection. Selecting a predetermined phase shift provided by the phase shifter 230 to produce a predetermined phase difference (e.g., 90 degrees, 180 degrees, etc.) in the connections is used to either set or change the phase state. For example, in a first switch state corresponding to a first phase shift of the phase shifter 230 (i.e., a first phase state), a signal entering the MZI optical switch 200 may exist at a first output port 224a of the second coupler 220. In a second switch state corresponding to a second phase shift of the phase shifter 230 (i.e., a second phase state), the signal may exit the MZI optical switch 200 at a second output port 224b of the second coupler 220, for example. As such, the MZI optical switch 200 illustrated in FIG. 3A implements at least a single pole, double throw (1PDT) switch. In fact, the MZI optical switch 200 generally implements a double pole, double throw (2PDT) switch by virtue of the pair of input ports 212a, 212b of the first coupler 210. According to some examples, the optical crossbar switch 110 of FIG. 2 may include the optical switch 200 illustrated in FIG. 3A.

FIG. 3B illustrates a top view of an optical switch 200, according to another example consistent with the principles described herein. As illustrated, the optical switch 200 illustrated in FIG. 3B is a multimode interferometer (MMI) coupler based, Mach-Zehnder interferometer (MZI) based optical switch 200. Further, the optical switch 200 illustrated in FIG. 3B is on a semiconductor substrate 240 (e.g., an SOI substrate). In particular (e.g., as illustrated in FIG. 3B), the MMI coupler based, MZI based optical switch 200 may employ two-by-two (2×2) MMI couplers for both the first coupler 210 and the second coupler 220. The 2×2 MMI couplers 210, 220 may each include a slab waveguide portion 210′, 220′, an input port portion 212, 222 and an output port portion 214, 224. The input and output port portions 212, 222, 214, 224 may be implemented as optical waveguides. As illustrated, the 2×2 MMI couplers 210, 220 are interconnected by additional optical waveguides 250. The optical waveguides 250 illustrated in FIG. 3B may be strip waveguides, for example.

Further, the phase shifter 230 is illustrated as electrodes 232 (cross-hatched regions) covering a portion of the addition optical waveguides 250 connecting the first and second 2×2 MMI couplers 210, 220 in FIG. 3B. In other examples (not illustrated), another coupler such as, but not limited to, a parallel line coupler and a ring resonator coupler may be employed as one or both of the couplers 210, 220. According to some examples, the optical crossbar switch 110 of FIG. 2 may include the optical switch 200 illustrated in FIG. 3B.

FIG. 3C illustrates a schematic view of an optical switch 200, according to yet another example consistent with the principles described herein. The optical switch 200 illustrated in FIG. 3C is on a semiconductor substrate 240 (e.g., an SOI substrate). In particular, FIG. 3C illustrates an N by N optical switch 200 implemented as an N by N generalized Mach-Zehnder interferometer (N×N GMZI) 200. As illustrated, the N×N GMZI optical switch 200 includes a first multimode interference (MMI) coupler 210 having N inputs and N outputs and a second MMI coupler 220 also having N inputs and N outputs. The N×N GMZI optical switch 200 further includes a plurality of N optical phase shifters 230 connecting the N outputs of the first MMI coupler 210 to the N inputs of the second MMI coupler 220. According to some examples, the optical crossbar switch 110 may include the optical switch 200 illustrated in FIG. 3C. In particular, the N inputs of the first MMI coupler 210 may correspond to the N input ports 112 of the optical crossbar switch 100 and the N outputs of the second MMI coupler 220 may correspond to the N output ports 114 of the optical crossbar switch 110 illustrated in FIG. 2, according to some examples.

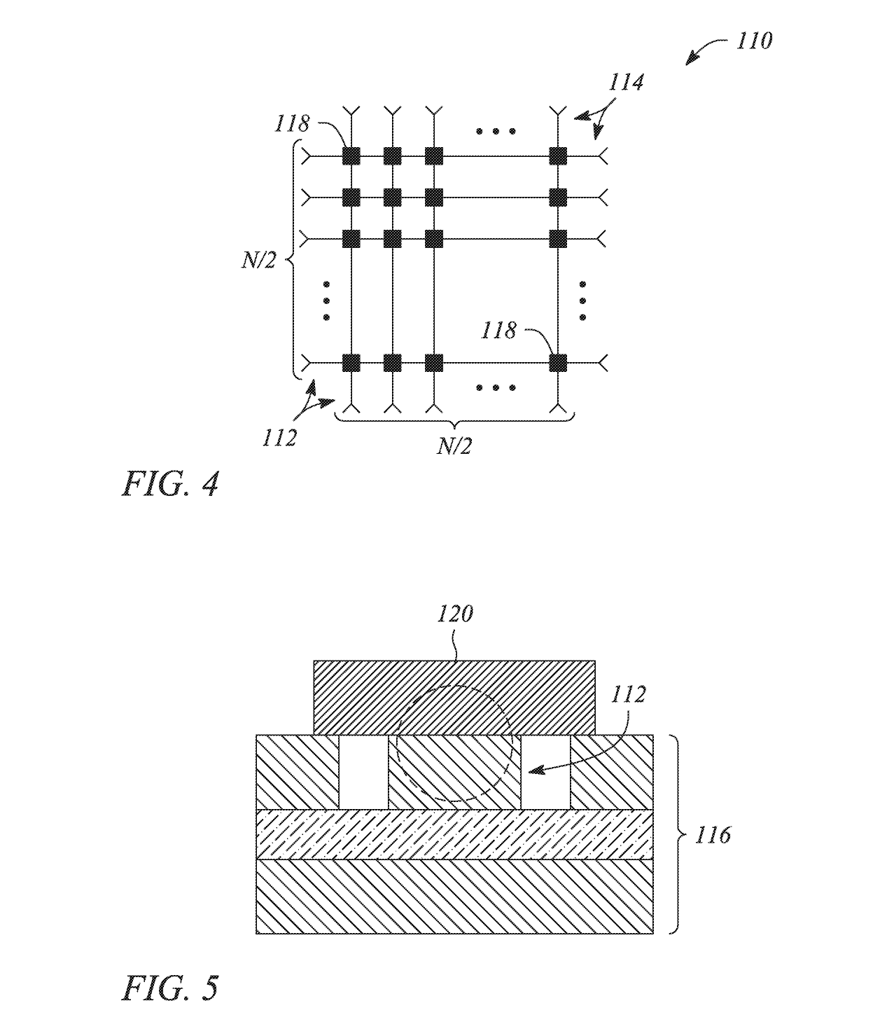

FIG. 4 illustrates a schematic view of an optical crossbar switch 110, according to an example consistent with the principles described herein. As illustrated, the optical crossbar switch 110 includes N input ports 112 and N output ports 114. Switches 118 enable an optical signal at any one of the input ports 112 to be routed to any one or more of the output ports 114. The switches 118 may be implemented using the optical switches illustrated in FIGS. 3A-3C or another optical switch (e.g., a total internal reflection optical switch), for example.

Referring again to FIG. 2, the loss compensated optical switch 100 further includes a wafer bonded semiconductor optical amplifier (SOA) 120. As illustrated, the wafer bonded SOA 120 is optically coupled to an input port 112 of the optical crossbar switch 110 to amplify an optical signal at the input port 112. In other examples (not illustrated), the wafer bonded SOA 120 may be optically coupled to an output port 114 or even located within and optically coupled to an optical waveguide of the optical crossbar switch 110 itself. In some examples (not illustrated), another component (e.g., a filter) may be located between the SOA 120 and the optical crossbar switch 110. In other words, the ports 112, 114 may be defined as being beyond the other component, for example.

The optical coupling may be an evanescent coupling from an optical waveguide (e.g., of the ports 112, 114) into the active or amplifying region of the SOA, for example. The wafer bonded SOA 120 includes a layer of a second semiconductor material that is wafer bonded to a surface of the substrate 116 such that a portion of the wafer bonded SOA semiconductor material layer overlies a portion of the input port 112 (e.g., an optical waveguide of the input port 112). In some examples, the wafer bonded SOA 120 is optically coupled to the input port 112 of the optical crossbar switch 110 by adjusting the height (e.g., ‘thinning’) of a strip or slab of an optical waveguide of the input port 112, for example. This height adjustment may serve to increase an amount of an optical field that extends outside of (e.g., above) the optical waveguide to increase evanescent coupling into the wafer bonded SOA 120, for example.

According to various examples, the second semiconductor material is different from the first semiconductor material of the substrate 116 on which the optical crossbar switch 110 is located. For example as discussed above, the first semiconductor material may be or include Si and the second semiconductor material of the wafer bonded SOA 120 may be or include, but is not limited to, a III-V compound semiconductor, an II-VI semiconductor, and a variety of other semiconductor materials that provide optical gain (e.g., so-called ‘direct’ bandgap semiconductors). In various examples, a maximum amplification or gain occurs at photon energies just above a bandgap energy of the second semiconductor material. In particular, the substrate 116 may be a silicon SOI substrate 116 with a wafer bonded layer of III-V compound semiconductor material attached to the surface of the silicon SOI substrate 116 and extending over an optical waveguide formed or otherwise provided in the silicon surface layer of the SOI substrate 116, for example. Examples of III-V compound semiconductors that may be employed as the second semiconductor material include, but are not limited to, gallium arsenide (GaAs), aluminum gallium arsenide (AlGaAs), indium phosphide (InP), indium gallium arsenide (InGaAs), aluminum indium GaAs (AlInGaAs), and indium gallium arsenide phosphide (InGaAsP).

In some examples (e.g., as illustrated in FIG. 2), the loss compensated optical switch 100 includes a plurality of the wafer bonded SOAs 120. In particular, in some examples, each input port 112 of the plurality of input ports 112 of the optical crossbar switch 110 is optically coupled to a different one of the wafer bonded SOAs 120. In other examples (not illustrated), there may be fewer wafer bonded SOAs 120 than there are input ports 112. In some examples, an optical gain of the wafer bonded SOA 120 may be adjustable (e.g., by increasing a drive current of the wafer bonded SOA 120). For example, the optical gain may be adjusted to be substantially equal to and thus compensate for a loss through the optical crossbar switch 110 for a particular optical signal routing or switch state.

In some examples, the optical gain adjustment may be predetermined, while in other examples, the optical gain adjustment may be varied in situ to compensate for loss that may vary during the operation of the loss compensated optical switch 100. For example, the optical gain adjustment may be varied in situ, according to a configuration (e.g., switch state) of the loss compensated optical switch 100.

In other examples (not illustrated), the plurality of wafer bonded SOAs 120 may be located on each of the output ports 114. In yet other examples (not illustrated), the plurality of wafer bonded SOAs 120 may be located on one or both of the input and output ports 112, 114. In still other examples, one or more of the wafer bonded SOAs 120 may be placed or distributed within the optical crossbar switch 110 itself.

FIG. 5 illustrates a cross sectional view of a wafer bonded semiconductor amplifier (SOA) 120, according to an example consistent with the principles described herein. As illustrated, the wafer bonded SOA 120 is wafer bonded to a surface of the SOI substrate 116. An input port 112 of the optical crossbar switch (not illustrated in FIG. 5) is an optical waveguide (e.g., a strip waveguide) passing under the wafer bonded SOA 120, as illustrated. An optical field within the optical waveguide of the input port 112 is illustrated using a circular dashed line in FIG. 5 as extending into an active region of the wafer bonded SOA 120. The extension of the optical field into the SOA 120 provides optical coupling through an evanescent field coupling (e.g., by optical waveguide thinning) to enable optical amplification by the wafer bonded SOA 120.

Furthermore, while illustrated as a single layer in FIG. 5, the wafer bonded SOA 120 may actually include more layers than just one, according to various examples. In addition, the wafer bonded SOA 120 may further include one or more dopants and dopant concentrations as well as an electrical connection to other components or power sources (e.g., an electrode). The dopants and dopant concentrations and the electrical connection may be used to realize a particular type or functionality of the wafer bonded SOA 120 (e.g., optical gain). The electrical connection may be used to power (e.g. electrically pump) the wafer bonded SOA 120.

For example, the wafer bonded SOA 120 may include a diode junction including, but not limited to, a p-n junction, a p-i-n junction, and a heterostructure diode junction. Heterostructures diode junctions may be made up of a plurality of variously doped (e.g., n, n+, p, and p+) layers, for example. In another example, the wafer bonded SOA 120 may include a quantum well such as those often used for solid state (e.g., diode) lasers and non-wafer bonded optical amplifiers. In yet another example, the wafer bonded SOA 120 may include a plurality of variously doped layers arranged as a separate confinement heterostructure laser structure.

As illustrated in FIG. 5, an approximate extent of the optical signal is depicted as a circular dashed line, as noted above. The circular dashed line extends into the second semiconductor material layer of the wafer bonded SOA 120. As such, a portion of the optical signal is coupled into and propagates within the wafer bonded SOA 120, as illustrated. The portion of the optical signal propagating within the wafer bonded SOA 120 is available to be influenced or amplified by the wafer bonded SOA 120, according to various examples.

Referring again to FIG. 2, in some examples, the loss compensated optical switch 100 may further include a filter 130 to selectively filter an optical signal passing through the loss compensated optical switch 100. For example, as illustrated in FIG. 2, the filter 130 may be located at the output port 114 of the optical crossbar switch 110. In other examples (not illustrated), the filter 130 may be located at another location such as, but not limited to, a space or length of optical waveguide between the wafer bonded SOA 120 and the input port 112 of the optical crossbar switch 110. In various examples, the filter 130 is configured to selectively filter out (e.g., substantially attenuate or otherwise reject) amplified spontaneous emissions produced by the wafer bonded SOA 120.

In some examples, the filter 130 may include a sampled grating, distributed Bragg reflector (SG-DBR) optical filter 130. The SG-DBR optical filter 130 may include a plurality of spaced apart diffraction gratings that together provide a reflection spectrum having or exhibiting a periodic maxima at a wavelength of interest. In particular, the SG-DBR optical filter 130 may be realized as a diffraction grating at a predetermined wavelength multiplied by a sampling function to produce the spaced apart diffraction gratings. In various examples, the diffraction gratings of the SG-DBR optical filter 130 may be formed or otherwise provided in a surface of the substrate (e.g., the SOI substrate).

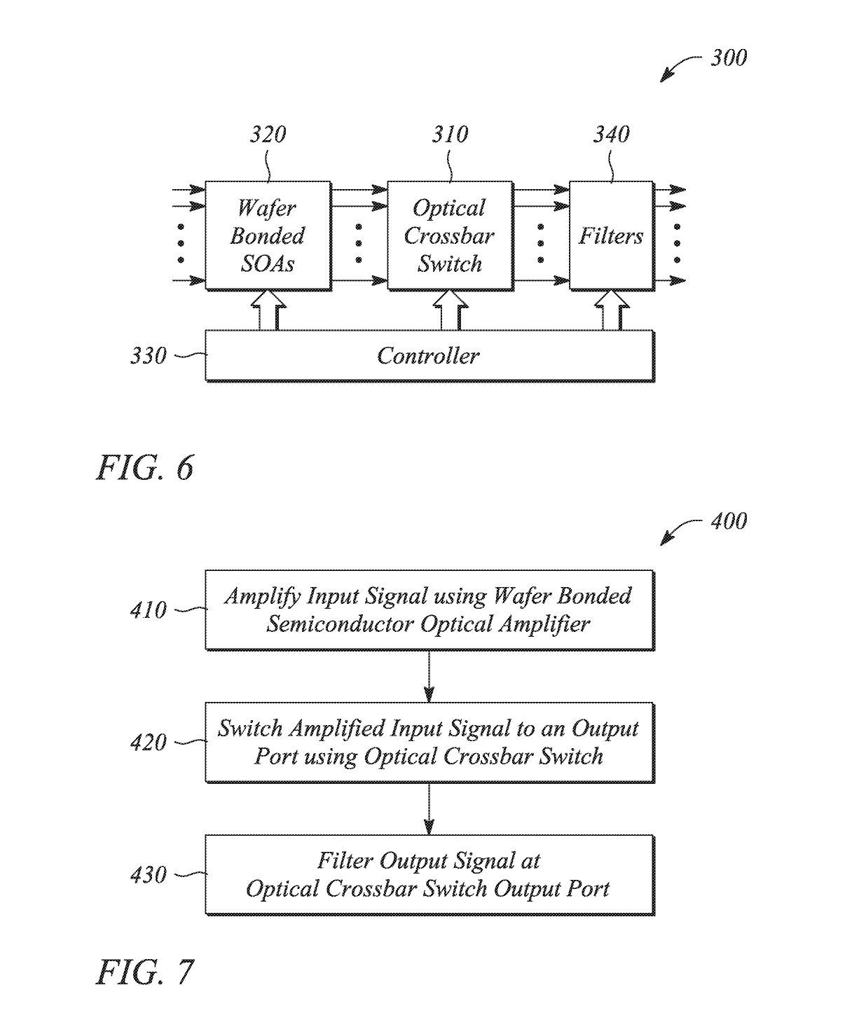

FIG. 6 illustrates a block diagram of a loss compensated optical switch system 300, according to an example consistent with the principles described herein. As illustrated, the loss compensated optical switch system 300 includes an optical crossbar switch 310. In some examples, the optical crossbar switch 310 may be substantially similar to the optical crossbar switch 110 described above with respect to the loss compensated optical switch 100. In particular, in some examples, the optical crossbar switch 310 may be on a silicon-on-insulator (a silicon SOI) substrate. Further, the optical crossbar switch 310 may have N input ports and N output ports, where N is an integer greater than one, according to some examples. As such, the optical crossbar switch 310 may be an N by N optical crossbar switch 310. In some examples, optical crossbar switch 310 may include an N by N generalized Mach-Zehnder Interferometer (N×N GMZI). In other examples, the optical crossbar switch 310 may have N input ports and M output ports, both N and M being integers greater than one that may be equal or unequal.

The loss compensated optical switch system 300 further includes a plurality of wafer bonded semiconductor optical amplifiers (SOAs) 320. For example, there may be N wafer bonded SOAs 320 in the plurality. In some examples, the wafer bonded SOAs 320 are substantially similar to the wafer bonded SOAs 120 of the loss compensated optical switch 100, described above. In particular, each wafer bonded SOA 320 of the plurality overlies and is optically coupled to a different one of the ports of the optical crossbar switch 310 (e.g., the N input ports, the N output ports or a combination thereof), according to various examples. Further, according to various examples, the wafer bonded SOAs 320 include a layer of a semiconductor material that differs from silicon (Si) and that is wafer bonded to a surface of the silicon SOI substrate. For example, the semiconductor material of the wafer bonded SOAs 320 may include, but is not limited to, a III-V compound semiconductor and a II-VI compound semiconductor. The wafer bonded SOAs 320 may include, but are not limited to, one or more layers of gallium arsenide (GaAs), aluminum gallium arsenide (AlGaAs), indium phosphide (InP), indium gallium arsenide (InGaAs), aluminum indium GaAs (AlInGaAs), and indium gallium arsenide phosphide (InGaAsP). One or more of the layers may be doped with either a p-type dopant or an n-type dopant such that the layers provide a semiconductor junction (e.g., p-n diode junction, p-i-n diode junction, heterostructure diode junction, etc.), for example. The layers may also form a quantum well.

As illustrated in FIG. 6, the loss compensated optical switch system 300 further includes a controller 330. The controller 330 is configured to control the optical crossbar switch 310. In particular, the controller 330 is configured to control switch states of the optical crossbar switch 310 to route signals from an input port (e.g., one of the N input ports) to one or more of the output ports. The controller 330 may provide electrical signals to electrodes within the optical crossbar switch 310. The electrical signals may change a phase shift of a phase shifter, for example, to change the switch state, for example. In some examples, the controller 330 may further provide control signals to the wafer bonded SOAs 320. For example, the controller 330 may control a gain level of the wafer bonded SOAs 320.

In some examples, the loss compensated optical switch system 300 further includes a plurality of filters 340 to selectively filter optical signals within the loss compensated optical switch system 300. According to some examples, each filter of the plurality of filters 340 may be connected to a different one of the output ports (e.g., N output ports) of the optical crossbar switch 310. In some examples, a filter 340 of the plurality is substantially similar to the filter 130 described above with respect to the loss compensated switch 100. In particular, in some examples, the filter 340 may include a sampled grating distributed Bragg reflector (SG-DBR) optical filter 340. As such, there may be a total of N SG-DBR optical filters 340 on the N outputs of the optical crossbar switch 310.

In some examples, a wavelength of the filters 340 is tunable. For example, a wavelength of the SG-DBR optical filter 340 may be tuned by application of an electric signal to change a refractive index of a material of the SG-DBR optical filter 340. In some examples, the controller 330 may provide the electric signal to tune the filter wavelength. The filter 340 may be selectively tuned to a wavelength band corresponding to a signal that is to be transmitted through the loss compensated optical switch system 300, for example.

FIG. 7 illustrates a flow chart of a method 400 of loss compensated optical switching, according to an example consistent with the principles described herein. The method 400 of loss compensated optical switching includes amplifying 410 an optical signal at a port (e.g., one or both of an input port and an output port) of an optical crossbar switch using a semiconductor optical amplifier (SOA). Note that, while the optical signal that is amplified 410 is at a port, in general amplifying 410 may occur elsewhere (e.g., within the optical crossbar switch, after another component connected in series with the port, etc.).

According to various examples, the optical crossbar switch includes a first semiconductor material and the SOA includes a layer of a second semiconductor material that is wafer bonded to a surface of the first semiconductor material. For example, the first semiconductor material may be a silicon (Si) and the second semiconductor may include, but is not limited to, a III-V compound semiconductor and a II-VI compound semiconductor. In some examples, the optical crossbar switch may be implemented on a silicon-on-insulator (a silicon SOI) substrate where an Si layer of the SOI substrate is the first semiconductor material layer. As such, the SOA of amplifying 410 may be a wafer bonded SOA. Further, according to some examples, the wafer bonded SOA may be substantially similar to the wafer bonded SOA 120 described above with respect to the loss compensated optical switch 100.

The method 400 of loss compensated optical switching further includes switching 420 the optical signal to one or more of a plurality of output ports using the optical crossbar switch. In various examples, switching 420 may occur one or both of before and after amplifying 410 the optical signal. In some examples, switching 420 includes selectively inducing a change in a refractive index of a portion of the first semiconductor material in a vicinity of a switch within the optical crossbar switch. In some examples, the optical crossbar switch is substantially similar to the optical crossbar switch 110 of the loss compensated optical switch 100, described above.

In some examples, the method 400 of loss compensated optical switching further includes filtering 430 an output signal at an output port of the optical crossbar switch. In some examples, filtering 430 uses a sampled grating, distributed Bragg reflector (SG-DBR) optical filter. The filter and more particularly the SG-DBR optical filter used in filtering 430 may be substantially similar respectively to the optical filter 130 and SG-DBR optical filters 130, 340 described above with respect to the loss compensated optical switch 100 and loss compensated optical switching system 300, in some examples.

Thus, there have been described examples of a loss compensated optical switch, a loss compensated optical switching system and a method loss compensated optical switching that employ a wafer bonded semiconductor optical amplifier. It should be understood that the above-described examples are merely illustrative of some of the many specific examples that represent the principles described herein. Clearly, those skilled in the art can readily devise numerous other arrangements without departing from the scope as defined by the following claims.

What is claimed is:

1. A loss compensated optical switch comprising:
an optical crossbar switch having a plurality of input ports and a plurality of output ports, the optical crossbar switch being on a substrate comprising a first semiconductor material; and
a wafer bonded semiconductor optical amplifier (SOA) optically coupled to a port of the optical crossbar switch to amplify an optical signal at the port,
wherein the wafer bonded SOA comprises a layer of a second semiconductor material that is wafer bonded to a surface of the substrate such that a portion of the wafer bonded SOA semiconductor material layer overlies a portion of an optical waveguide of the port, the second semiconductor material being different from the first semiconductor material.

2. The loss compensated optical switch of claim 1, wherein the plurality of input ports has N input ports and the plurality of output ports has M output ports, the optical crossbar switch to connect any one of the N input ports to one or more of the M output ports, where N and M both are integers greater than one.

3. The loss compensated optical switch of claim 2, wherein M equals N such that the optical crossbar switch has the same number of input ports as there are output ports.

4. The loss compensated optical switch of claim 1, wherein the optical crossbar switch comprises a Mach-Zehnder interferometer optical switch comprising:
a first coupler;
a second coupler, an output of the first coupler being connected to an input of the second coupler to provide a connection; and
a phase shifter in the connection between the first and second couplers.

5. The loss compensated optical switch of claim 4, wherein one or both of the first and second couplers comprise a multimode interference coupler.

6. The loss compensated optical switch of claim 1, wherein the optical crossbar switch is an N by N generalized Mach-Zehnder interferometer comprising:
a first multimode interference (MMI) coupler having N inputs and N outputs;
a second MMI coupler having N inputs and N outputs; and
a plurality of N optical phase shifters connecting the N outputs of the first MMI coupler to the N inputs of the second MMI coupler,
wherein the N inputs of the first MMI coupler represent the N input ports of the optical crossbar switch and the N outputs of the second MMI coupler represent the N output ports of the optical crossbar switch, where N is an integer greater than one.

7. The loss compensated optical switch of claim 1, wherein the wafer bonded SOA is one of a plurality of the wafer bonded SOAs, each wafer bonded SOA of the plurality being optically coupled to a different one of the optical crossbar switch ports.

8. The loss compensated optical switch of claim 1, wherein the second semiconductor material of the wafer bonded SOA semiconductor material layer comprises a III-V compound semiconductor and the first semiconductor material of the substrate comprises silicon.

9. The loss compensated optical switch of claim 8, wherein the substrate is a silicon semiconductor-on-insulator (SOI) substrate, the input and output ports comprising optical waveguides provided in a silicon surface of the SOI substrate.

10. The loss compensated optical switch of claim 1, further comprising a sampled grating distributed Bragg reflector (SG-DBR) optical filter on an output port of the optical crossbar switch, the SG-DBR optical filter to selectively filter an optical signal at the output port.

11. A loss compensated optical switching system comprising:
an optical crossbar switch on a silicon semiconductor-on-insulator (SOI) substrate, the optical crossbar switch having N input ports and N output ports, where N is an integer greater than one;
a plurality of N wafer bonded semiconductor optical amplifiers (SOA), each wafer bonded SOA of the plurality overlying and being optically coupled to a different one of the ports of the optical crossbar switch; and
a controller to control the optical crossbar switch,
wherein the wafer bonded SOAs comprise a layer of a semiconductor material that differs from silicon and that is wafer bonded to a surface of the silicon SOT substrate.

12. The loss compensated optical switch system of claim 11, wherein the optical crossbar switch comprises an N by N generalized Mach-Zehnder Interferometer.

13. The loss compensated optical switch system of claim 11, further comprising a plurality of N sampled grating distributed Bragg reflector (SG-DBR) optical filters, each SG-DBR optical filter of the plurality being connected to a different one of the N output ports of optical crossbar switch, wherein diffraction gratings of the SG-DBR optical filters are provided in a surface of the silicon SOI substrate to selectively filter an optical signal at each of the N output ports.

14. A method of loss compensated optical switching, the method comprising:
amplifying an optical signal at a port of an optical crossbar switch using a semiconductor optical amplifier (SOA), the optical crossbar switch comprising a first semiconductor material, the SOA comprising a layer of a second semiconductor material that is wafer bonded to a surface of the first semiconductor material, the first and second semiconductor materials being different; and
switching the optical signal to one or more of a plurality of output ports using an optical crossbar switch, switching occurring one or both of before and after amplifying the optical signal.

15. The method of loss compensated optical switching of claim 14, further comprising filtering an output optical signal at an output port of the optical crossbar switch using a sampled grating distributed Bragg reflector optical filter, wherein switching the optical signal using the optical crossbar switch comprises:
passing the optical signal through a first multimode interference (MMI) coupler to split the optical signal into at least two portions;
differentially phase shifting one of the at least two portions of the optical signal relative to another of the at least two portions using a phase shifter; and
passing the at least two optical signal portions through a second MMI coupler to recombine the at least two optical signal portions into an output optical signal at a selected output of the second MMI coupler, the selected output being determined by the differential phase shift applied to the at least two optical signal portions by the phase shifter.
